(19) United States
(12) Patent Application Publication
(10) Pub. No.: US 2024/0341128 A1
(43) Pub. Date: Oct. 10, 2024

(54) DISPLAY PANEL AND DISPLAY DEVICE

(71) Applicants: WUHAN TIANMA MICROELECTRONICS CO., LTD., Wuhan (CN); WUHAN TIANMA MICROELECTRONICS CO., LTD. SHANGHAI BRANCH, Shanghai (CN)

(72) Inventor: Huiping CHAI, Shanghai (CN)

(73) Assignees: WUHAN TIANMA MICROELECTRONICS CO., LTD., Wuhan (CN); WUHAN TIANMA MICROELECTRONICS CO., LTD. SHANGHAI BRANCH, Shanghai (CN)

(21) Appl. No.: 18/747,469

(22) Filed: Jun. 19, 2024

(30) Foreign Application Priority Data
Jul. 24, 2023 (CN) 202310913630.7

(51) Int. Cl. H10K 59/122; H10K 59/35

(52) U.S. Cl. CPC H10K 59/122; H10K 59/352; H10K 59/353

(57) ABSTRACT

A display panel and a display device are provided. The display panel includes a substrate, a pixel definition layer and multiple pixels. The pixel definition layer is arranged on a side of the substrate. The pixel definition layer includes a pixel limiting part and a pixel opening defined by the pixel limiting part. The pixel includes a first electrode and a light emitting structure at least partially arranged in the pixel opening. The pixel opening at least partially exposes at least the first electrode. An orthographic projection of the pixel opening on the substrate is a first shape at least partially includes a curved edge. The light emitting structure is formed in the pixel opening by evaporation, printing, or the like, after the pixel definition layer. Therefore, the light emitting structure is relatively round and then less dispersion results.

### CROSS-REFERENCE TO RELATED APPLICATION

The present application claims the priority to Chinese Patent Application No. 202310913630.7, titled “DISPLAY PANEL AND DISPLAY DEVICE”, filed on Jul. 24, 2023 with the China National Intellectual Property Administration, which is incorporated herein by reference in its entirety.

### FIELD

The present disclosure relates to the field of displays, and in particular to a display panel and a display device.

### BACKGROUND

As technologies advance, electronic devices develop rapidly and are widely used. Increasingly high demands are imposed on the electronic devices, e.g., display panels. However, the existing display panels are prone to dispersion during use, which seriously interferes with proper display, resulting in relatively poor user experience.

### SUMMARY

A display panel and a display device are provided according to the embodiments of the present disclosure, to prevent dispersion.

A display panel is provided according to the embodiments of the present disclosure. The display panel includes a substrate, a pixel definition layer and multiple pixels. The pixel definition layer is arranged on a side of the substrate. The pixel definition layer includes a pixel limiting part and a pixel opening defined by the pixel limiting part. The pixel includes a first electrode and a light emitting structure at least partially arranged in the pixel opening. The pixel opening at least partially exposes the first electrode. An orthographic projection of the pixel opening on the substrate is a first shape. The first shape includes at least a curved edge.

In one embodiment, a display device is provided according to the embodiments of the present the present disclosure. The display device includes the display panel described above.

### BRIEF DESCRIPTION OF THE DRAWINGS

In order to more clearly describe the embodiments of the present disclosure, drawings to be used in the description of the embodiments of the present disclosure are briefly described hereinafter.

FIG. 1 is a schematic structural diagram illustrating a display panel according to an embodiment of the present disclosure;

FIG. 2 is a schematic structural diagram illustrating an enlarged region Q of the display panel as illustrated in FIG. 1;

FIG. 3 is a sectional view of the display panel cut along a line indicated by A-A as illustrated in FIG. 2;

FIG. 4 is a schematic structural diagram illustrating the enlarged region Q of the display panel according to another embodiment of the present disclosure;

FIG. 5 is a schematic structural diagram illustrating the enlarged region Q of the display panel according to another embodiment of the present disclosure;

FIG. 6 is a schematic diagram illustrating a display effect of a display panel in the prior art

FIG. 7 is a schematic diagram illustrating another display effect of a display panel in the prior art

FIG. 8 is a schematic diagram illustrating a display effect of a display panel according to an embodiment of the present disclosure;

FIG. 9 is a schematic structural diagram illustrating the enlarged region Q of the display panel according to another embodiment of the present disclosure;

FIG. 10 is a schematic structural diagram illustrating the enlarged region Q of the display panel according to another embodiment of the present disclosure;

FIG. 11 is a schematic structural diagram illustrating the enlarged region Q of the display panel according to another embodiment of the present disclosure;

FIG. 12 is a schematic structural diagram illustrating the enlarged region Q of the display panel according to another embodiment of the present disclosure;

FIG. 13 is a schematic structural diagram illustrating the enlarged region Q of the display panel according to another embodiment of the present disclosure;

FIG. 14 is a schematic structural diagram illustrating the enlarged region Q of the display panel according to another embodiment of the present disclosure;

FIG. 15 is a schematic structural diagram illustrating the enlarged region Q of the display panel according to another embodiment of the present disclosure;

FIG. 16 is a schematic structural diagram illustrating the enlarged region Q of the display panel according to another embodiment of the present disclosure;

FIG. 17 is a sectional view of the display panel cut along a line indicated by C-C as illustrated in FIG. 16;

FIG. 18 is a schematic structural diagram illustrating the enlarged region Q of the display panel according to another embodiment of the present disclosure;

FIG. 19 is a schematic diagram briefly illustrating a first pixel circuit in the display panel according to an embodiment of the present disclosure;

FIG. 20 is a schematic circuit diagram of the display panel according to an embodiment of the present disclosure;

FIG. 21 is a schematic diagram briefly illustrating a second pixel circuit in the display panel according to an embodiment of the present disclosure;

FIG. 22 is a schematic structural diagram illustrating the enlarged region Q of the display panel according to another embodiment of the present disclosure;

FIG. 23 is sectional view of the display panel cut along a line indicated by B-B as illustrated in FIG. 22;

FIG. 24 is a schematic structural diagram illustrating the enlarged region Q of the display panel according to another embodiment of the present disclosure;

FIG. 25 is a schematic circuit diagram of the display panel according to an embodiment of the present disclosure;

FIG. 26 is a sectional view of the display panel cut along a line indicated by D-D as illustrated in FIG. 25; and

FIG. 27 is a schematic structural diagram illustrating a display device according to an embodiment of the present disclosure.

Reference numerals are listed as follows.

| | | | |
|---|---|---|---|
| 10 | substrate | | |
| 20 | pixel definition layer | 21 | pixel limiting part |
| 22 | pixel opening | 221 | first pixel opening |
| 222 | second pixel opening | 223 | aperture |
| 223a | first aperture | 2231 | first-type aperture |
| 2232 | second-type aperture | | |
| 30 | pixel | 31 | first electrode |
| 32 | light emitting structure | 321 | first light emitting structure |
| 321a | first-type light emitting structure | 321b | second-type light emitting structure |
| 321c | third-type light emitting structure | 322 | second light emitting structure |
| 323 | third light emitting structure | 33 | second electrode |
| 40 | first pixel circuit | 41 | first driving transistor |
| 42 | first threshold compensation transistor | | |
| 50 | second pixel circuit | 51 | second driving transistor |
| 52 | second threshold compensation transistor | | |
| 60 | light filtering layer | 61 | light shielding part |
| 62 | light filtering part | 63 | first aperture |
| 70 | data line | 80 | power supply line |
| X | first shape | | |
| D1 | first light emitting unit | D2 | pixel unit |
| B1 | first connecting part | B2 | second connecting part |
| J1 | first terminal | J2 | second terminal |
| J3 | gate | | |
| F | block structure | | |
| Z1 | first virtual straight line | Z2 | second virtual straight line |
| E1 | first edge | E2 | second edge |
| K | gap | | |
| X | first direction | Y | second direction |
| Z | third direction | | |

### DETAILED DESCRIPTION OF EMBODIMENTS

The features and exemplary embodiments of the present disclosure are described in detail below. The present disclosure is described in detail with reference to the drawings and the embodiments and of the present disclosure are understandable. It should be understood that the embodiments described herein are intended to explain the present disclosure only rather than limit the present disclosure. The present disclosure can be implemented without some of the details. The following description of the embodiments is intended to only provide a better understanding of the present disclosure by illustrating the embodiments of the present disclosure. It should be noted that terms such as “first” and “second” herein are only used to distinguish one entity or operation from another instead of necessitating or implying that there is an actual relation or sequence between these entities or operations. Moreover, terms of “include”, “comprise” or any other variants thereof are intended to be non-exclusive. Therefore, a process, method, article or device including a series of elements includes not only the elements but also other elements that are not explicitly listed, or also includes the elements inherent in the process, method, article or device. Unless expressively limited otherwise, the statement “including . . . ” does not exclude the case that other similar elements may exist in the process, method, article or device.

Planar display panels, for example, organic light emitting display (OLED) panels and display panels including light emitting diode (LED) devices, are widely applied to various consumer electronic products such as mobile phones, televisions, personal digital assistants, digital cameras, laptops, and desktop computers due to advantages such as high image quality, low power consumption, thin body, and wide range of applications, and therefore become the mainstream of display devices.

At present, rectangular pixel structures in the organic light emitting display panel are arranged in an array, and therefore a ray incident on the display panel is prone to diffraction after reflected. In addition, the refracted rays transmitted out of the pixel structures fail to be fully blocked by some film layers, resulting in longitudinal chromatic aberration especially in case of strong incident light e.g., from a spotlight or linear light. Consequently, the display panel displays a rainbow pattern or significant spatial separation of light, which interferes with the displayed information, resulting in poor user experience.

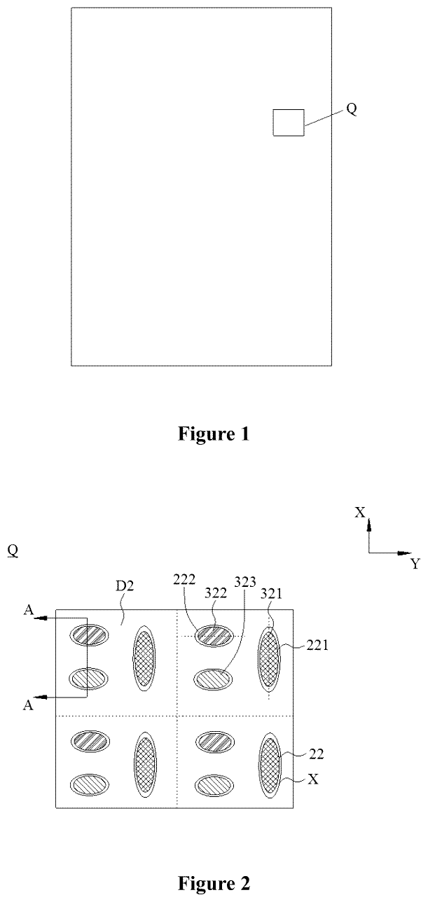

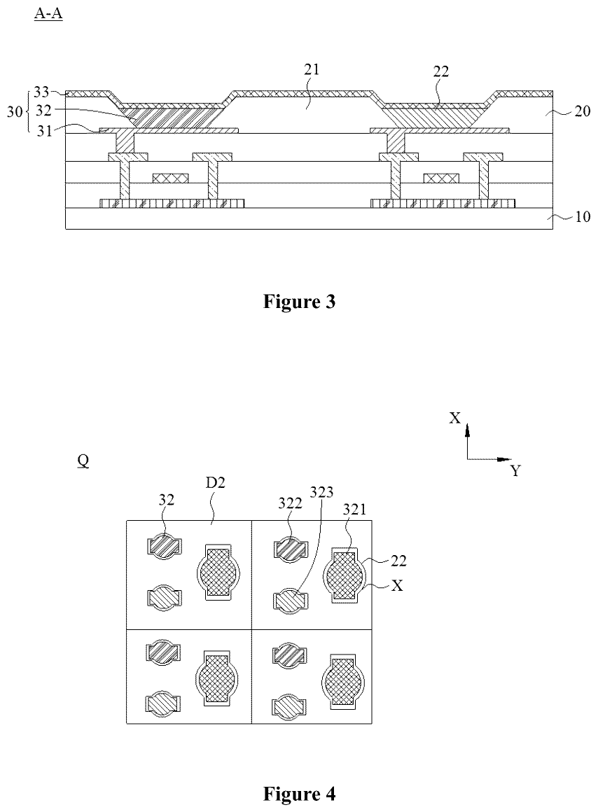

In order to solve the above problem, a display panel is provided according to the embodiments of the present disclosure. Referring to FIG. 1 to FIG. 3, the display panel includes a substrate 10, a pixel definition layer 20 and multiple pixels 30. The pixel definition layer 20 is arranged on a side of the substrate 10. The pixel definition layer 20 includes a pixel limiting part 21, and pixel openings 22 defined by the pixel limiting part 21. The pixels 30 each include a first electrode 31, and a light emitting structure 32 at least partially arranged in the pixel opening 22. The pixel opening 22 at least partially exposes the first electrode 31. An orthographic projection of the pixel opening 22 on the substrate 10 has a first shape X. The first shape X includes at least a curved edge.

The substrate 10 is mainly for supporting purposes. Other film layers are sequentially stacked on the substrate 10. That is, the other film layers are sequentially arranged on the substrate 10 along a thickness direction of the substrate 10. In addition to the pixel definition layer 20, the display panel further includes other film layers depending on practical situations, which is not limited in the embodiments of the present disclosure. In addition, a thickness direction of other film layers arranged on the side of the substrate 10 is normally the same as the thickness direction of the substrate 10. Therefore, for convenience of description, the thickness direction of the substrate 10 and the thickness direction of other film layers mentioned in subsequent embodiments of the present disclosure are illustrated as the same direction.

The pixel definition layer 20 and the multiple pixels 30 are arranged on the same side of the substrate 10. Further, the pixels 30 each have a light emitting surface and a light blocking surface. The substrate 10 is arranged on a side of the light blocking-surfaces of the pixels 30. That is, light emitted by the pixel 30 is transmitted out from the side of the pixel 30 away from the substrate 10.

The pixel definition layer 20 includes the pixel limiting part 21 and the pixel opening 22 defined by the pixel limiting part 21. The pixel 30 includes the first electrode 31 and the light emitting structure 32. The pixel opening 22 accommodates the light emitting structure 32. The first electrode 31 is connected to the light emitting structure 32 to transmit electrons or electron holes to the light emitting structure. In view of this, the pixel opening 22 at least partially exposes the first electrode 31, for connecting the first electrode 31 to the light emitting structure 32. In some embodiments, the pixel limiting part 21 partially covers the first electrode 31, and the first electrode 31 is partially exposed through the pixel opening 22. Therefore, the first electrode 31 is connected to the light emitting structure 32 to control the light emitting structure 32. The first electrode 31 may be a reflective electrode. For example, the first electrode 31 is made of one or more of silver (Ag)/indium tin oxide (ITO), ITO/Ag/ITO or titanium (Ti)/ITO.

A color of light emitted by the light emitting structure 32 is not limited in the embodiments of the present disclosure. In one embodiment, the light emitting structures 32 in the multiple pixels 30 include, but are not limited to, a red light emitting structure 32 configured to emit red light, a green light emitting structure 32 configured to emit green light, and a blue light emitting structure 32 configured to emit blue light. The light emitting structures 32 each includes a hole inject layer (HIL), a hole transport layer (HTL), a light emitting layer, an electron inject layer (EIL) and an electron transport layer (ETL) that are stacked. Light emitting layers in different pixels, when made of different materials, emit light in different colors under control of a driving signal. That is, the two pixels emit light in different colors.

Since the light emitting structures 32 in the respective pixels 30 are rectangular and arranged in the array, the display panel is prone to longitudinal chromatic aberration, as described above. In these embodiments, the pixel opening 22 is such modified that an orthographic projection of the pixel opening 22 on the substrate 10 has a first shape X, and the first shape X includes at least a curved edge. The first shape X mentioned in the embodiments of the present disclosure indicates an outer edge of the orthographic projection of the pixel opening 22 on the substrate 10. Apparently, the orthographic projection of the pixel opening 22 on the substrate 10 further has an inner edge (not illustrated in the drawings), which is not limited in the embodiments of the present disclosure. Since the pixel opening 22 is a three-dimensional structure, a side wall of the pixel opening 22 is normally inclined at an angle. That is, the side wall of the pixel opening 22 is not perpendicular to the substrate 10. Therefore, the orthographic projection of the pixel opening 22 on the substrate 10 includes a longer outer edge and a shorter inner edge.

The first shape X is in various forms. The outer edge of the first shape X is at least partially curved. In some embodiments, the outer edge of the first shape X is completely curved. In other embodiments, the outer edge of the first shape X is partially curved and partially straight or polygonal.

The light emitting structure 32 is normally formed after the pixel definition layer 20. The light emitting structure 32 is formed in the pixel opening 22 by a process such as evaporation or printing. Since the first shape X has at least a curved edge, the finally formed light emitting structure 32 is relatively round. Therefore, no pattern is resulted from refraction due to the arrangement of the light emitting structures 32. That is, refraction is prevented and therefore the display effect can be improved.

It should be noted that the pixel opening 22 has the same shape as the corresponding light emitting structure 32. In one embodiment, the pixel opening 22 has a slightly different shape from the corresponding light emitting structure 32, due to due to factors such as a difference in precision. That is, a contour of the orthographic projection of the light emitting structure 32 on the substrate 10 is unnecessarily coincides precisely with the first shape X. Therefore, with the first shape X having the curved edge, the light emitting structure 32 can be provided with a relatively round contour even if the orthographic projection of the light emitting structure 32 on the substrate 10 includes no curved edge, which also facilitates prevention of dispersion, to improve the display effect.

How the light emitting structures 32 are arranged in the display panel is not limited in the embodiments of the present disclosure. It should be noted that only one arrangement of the light emitting structures 32 is illustrated in FIG. 2. The arrangement of the light emitting structures 32 in the embodiments of the present disclosure is not limited thereto.

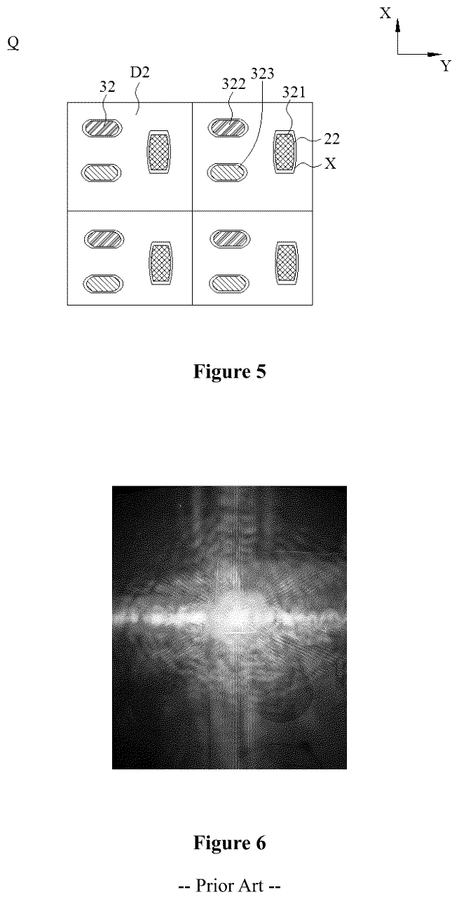

In addition, further details about the first shape X are not limited in the embodiments of the present disclosure, as long as the first shape X includes a curved edge. For example, the first shape X is irregular. As illustrated in FIG. 4, the first shape X is formed from a circle and a rectangle. In one embodiment, as illustrated in FIG. 5, the first shape X is formed by cutting a part from a circle or the like.

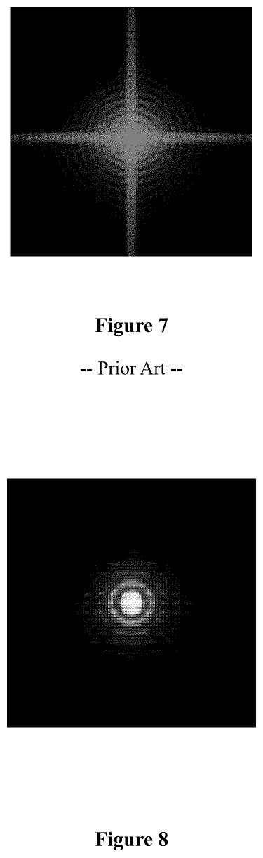

Reference is made to FIG. 6 to FIG. 8. It is founded from experiments that, under the same conditions, there is significant longitudinal chromatic aberration in case of spotlight or linear light when the orthographic projection of the pixel opening 22 on the substrate 10 has the straight or polygonal edge instead of curved edge, as illustrated in FIG. 6 and FIG. 7. When the orthographic projection of the pixel opening 22 on the substrate 10 has a curved edge, the display effect is as illustrated in FIG. 8. It can be seen that less dispersion results, and therefore the display effect is improved.

In some embodiments, the orthographic projections of at least some of the light emitting structures 32 on the substrate 10 include curved edges.

In some embodiments, as illustrated in FIG. 1 to FIG. 3, the pixels 30 further includes a second electrode 33 arranged on a side, of the light emitting structure 32, away from the substrate 10. The second electrode 33 cooperates with the first electrode 31 to control the light emitting structure 32 to emit light. The second electrode 33 is integrally formed structure. That is, an orthographic projection of the second electrode 33 on the substrate 10 covers orthographic projections of multiple light emitting structures 32 on the substrate 10. In one embodiment, the first electrode 31 is an anode and the second electrode 33 is a cathode.

In some embodiments, at least some of the first shapes X each are a circle or an ellipse.

The circle and the ellipse each include a curved edge. Compared with other shape with a curved edge, the circle and the ellipse have the rounder outer edge, which is conducive to roundness of the light emitting structure 32 at the edge. Therefore, light incident in the display is less refracted after reflected. In addition, at least some of the first shapes X each is a circle and an ellipse, roundness of the corresponding light emitting structures 32 can be improved, which is conducive to prevention of dispersion, to improve the display effect.

In some embodiments, the first shape X is an ellipse. The ellipse normally has a major axis and a minor axis. The major axis refers to a line connecting the farthest two points on the ellipse, and the minor axis refers to a line connecting the nearest two points on the ellipse. Major axes of respective first shapes X corresponding to different pixel openings 22 are parallel or intersect, which is not limited in the embodiments of the present disclosure.

In some embodiments, as illustrated in FIG. 2, the multiple light emitting structures 32 include a first light emitting structure 321 and a second light emitting structure 322. The first light emitting structure 321 is configured to emit light in a different color form the second light emitting structure 322. The multiple pixel openings 22 include a first pixel opening 221 corresponding to the first light emitting structure 321 and a second pixel opening 222 corresponding to the second light emitting structure 322. The first shape X corresponding to the first pixel opening 221 and the first shape X corresponding to the second pixel opening 222 each are an ellipse. The major axis of the ellipse corresponding to the first pixel opening 221 intersects with the major axis of the ellipse corresponding to the second pixel opening 222. In FIG. 2, the major axis is indicated by a dotted line.

The first light emitting structure 321 is configured to emit light in different color from the second light emitting structure 322. A color of the light emitted by the first light emitting structure 321 and a color of the light emitted by the second light emitting structure 322 are not limited in the embodiments of the present disclosure. in some embodiments, the first light emitting structure 321 is configured to emit light in blue, and the second light emitting structure 322 is configured to emit light in red. In one embodiment, the first light emitting structure 321 is configured to emit light in blue, and the second light emitting structure 322 is configured to emit light in green.

For preparation of the first light emitting structure 321 and the second light emitting structure 322, the multiple pixel openings 22 include the first pixel opening 221 for accommodating the first light emitting structure 321 and the second pixel opening 222 for accommodating the second light emitting structure 322. On this basis, in the embodiments of the present disclosure, the first shape X corresponding to the first pixel opening 221 and the first shape X corresponding to the second pixel opening 222 each are an ellipse, which is conducive to roundness of edges of the first light emitting structure 321 and the second light emitting structure 322. Therefore, less dispersion results and the display effect can be improved.

If the major axis of the ellipse corresponding to the first pixel opening 221 is parallel to the major axis of the ellipse corresponding to the second pixel opening 222, a length direction of the first light emitting structure 321 is parallel to a length direction of the second light emitting structure 322. In this case, serious dispersion results along a single direction, resulting in poor display effect.

In the embodiments of the present disclosure, the major axis of the ellipse corresponding to the first pixel opening 221 and the major axis of the ellipse corresponding to the second pixel opening 222 intersect. Therefore, less dispersion results, to facilitate even display. This leads to better user experience.

An angle between the major axis of the ellipse corresponding to the first pixel opening 221 and the major axis of the ellipse corresponding to the second pixel opening 222 is not limited in the embodiments of the present disclosure. In one embodiment, the major axis of the ellipse corresponding to the first pixel opening 221 is perpendicular to the major axis of the ellipse corresponding to the second pixel opening 222.

It should be noted that, except that the major axis of the ellipse corresponding to the first pixel opening 221 is different from the major axis of the ellipse corresponding to the second pixel opening 222, a contour of the ellipse corresponding to the first pixel opening 221 is identical to or different from a contour of the ellipse corresponding to the second pixel opening 222, which is not limited in the embodiments of the present disclosure.

In addition, the first light emitting structure 321 is integrally formed. In one embodiment, the first light emitting structure 321 include multiple separate parts. Further, the first pixel opening 221 corresponding to the first light emitting structure 321 includes one aperture or multiple apertures, which is not limited in the embodiments of the present disclosure. The second light emitting structure 322 is similar to the first light emitting structure 321.

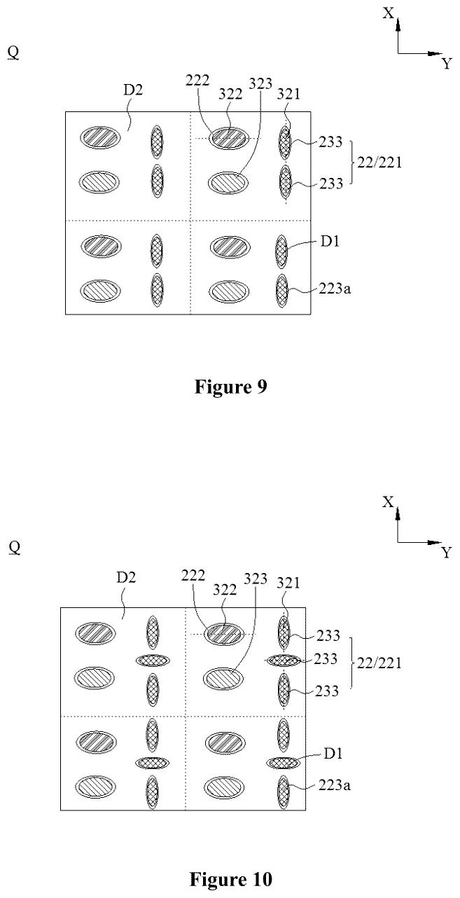

In some embodiments, referring to FIG. 9, at least some of the pixel openings 22 each include adjacent apertures 223. Orthographic projections of at least some of the apertures 223 on the substrate 10 each are a circle or ellipse.

It should be noted that multiple apertures 223 in the same pixel opening 22 are arranged apart. In one embodiment, one aperture 223 in a pixel opening 22 is arranged immediately adjacent to another aperture 223 in the pixel opening 22. In addition, the apertures 223 in the same pixel opening 22 are identical or different in shape, which is not limited in the embodiments of the present disclosure.

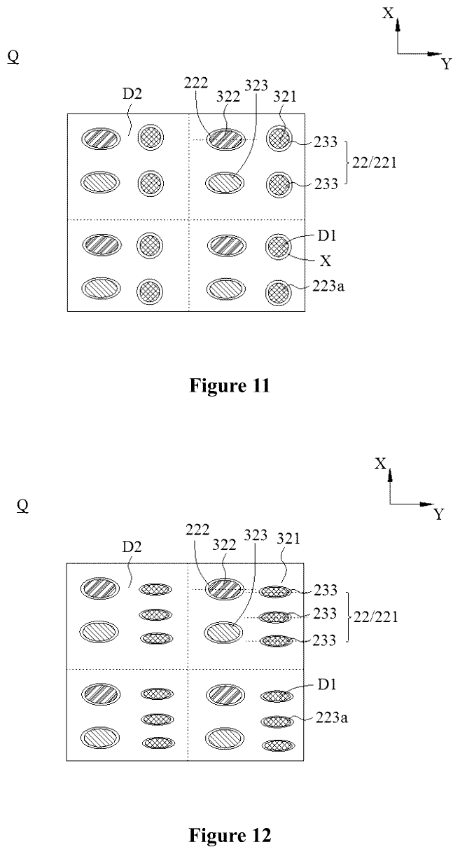

In some embodiments, one pixel opening 22 includes multiple apertures 223, and an orthographic projection of each of the apertures 223 on the substrate 10 is an ellipse. On this basis, as illustrated in FIG. 9, major axes of respective ellipses corresponding to the apertures 223 are parallel. In one embodiment, as illustrated in FIG. 10, major axes of respective ellipses corresponding to apertures 223 arranged on two sides are parallel, and a major axis of an ellipse corresponding to an aperture 223 arranged centrally intersects with the major axes of the ellipses corresponding to the apertures 223 arranged on two sides. In one embodiment, as illustrated in FIG. 11, the orthographic projections of the apertures 223 on the substrate each are a circle.

Normally, one light emitting structure 32 is arranged in one pixel opening 22. At least some of the pixel openings 22 each include adjacent apertures 223. For example, the pixel opening 22 corresponding to the first light emitting structure 321 includes multiple apertures 223, and the pixel opening 22 corresponding to the second light emitting structure 322 includes only one aperture. In a case that the pixel opening 22 corresponding to the first light emitting structure 321 includes multiple apertures 223, the multiple apertures 223 corresponding to the same first light emitting structure are driven by the same pixel circuit.

Further, in the embodiments of the present disclosure, orthographic projections of at least some of the apertures 223 on the substrate 10 each include is a circle or an ellipse, improving the roundness of the corresponding light emitting structures 32 at the edge of the apertures 223. Therefore, light incident in the display is less refracted after reflected. This is conducive to prevention of dispersion, to improve the display effect. In addition, when the light emitting material in one aperture 223 fails to emit light properly, the light emitting material in another aperture 223 can meet the demand on the light emitting structure 32 for emitting light. The light emitting structure 32 can emit light reliably and enduringly.

It should be noted that how the multiple apertures 223 in the same pixel opening 22 are arranged is not limited in the embodiments of the present disclosure. In some embodiments, the multiple apertures 223 in the same pixel opening 22 are arranged in a row. In one embodiment, the multiple apertures 223 in the same pixel opening 22 are arranged in rows and columns.

In some embodiments, as illustrated in FIG. 9, the multiple light emitting structures are divided into first light emitting structures 321, second light emitting structures 322, and third light emitting structure s323. The first light emitting structure 321, the second light emitting structure 322, and the third light emitting structure 323 are configured to emit light in different colors. The pixel opening 22 corresponding to the first light emitting structure 321 includes multiple apertures 223. The pixel opening 22 corresponding to the second light emitting structure 322 and the pixel opening 22 corresponding to the third light emitting structure 323 each include only one aperture. An orthographic projection of the aperture 223 corresponding to the first light emitting structure 321 on the substrate 10 is an ellipse. An orthographic projection of the pixel opening 22 corresponding to the second light emitting structure 322 on the substrate 10 and an orthographic projection of the pixel opening 22 corresponding to the third light emitting structure 323 on the substrate 10 each are an ellipse. It can be understood that the multiple apertures 223 corresponding to the first light emitting structure 321 are driven by the same pixel circuit (not illustrated in FIG. 9) to control the first light emitting structure 321 to emit light.

On this basis, as illustrated in FIG. 12, major axes of respective ellipses of the apertures 223 corresponding to the first light emitting structure 321 are parallel to the major axis of the ellipse of the pixel opening 22 corresponding to the second light emitting structure 322 and the major axis of the ellipse of the pixel opening 22 corresponding to the third light emitting structure 323. In one embodiment, as illustrated in FIG. 9, major axes of respective ellipses of the apertures 223 corresponding to the first light emitting structure 321 intersect with the major axis of the ellipse of the pixel opening 22 corresponding to the second light emitting structure 322 and the major axis of the ellipse of the pixel opening 22 corresponding to the third light emitting structure 323. Further, major axes of ellipses of the apertures 223 corresponding to the first light emitting structure 321 are perpendicular to the major axis of the ellipse of the pixel opening 22 corresponding to the second light emitting structure 322 and the major axis of the ellipse of the pixel opening 22 corresponding to the third light emitting structure 323.

In addition, the number of apertures 223 in each pixel opening 22, and how the apertures 223 are arranged depend on practical applications, for example, factors such as the aperture ratio and dispersion.

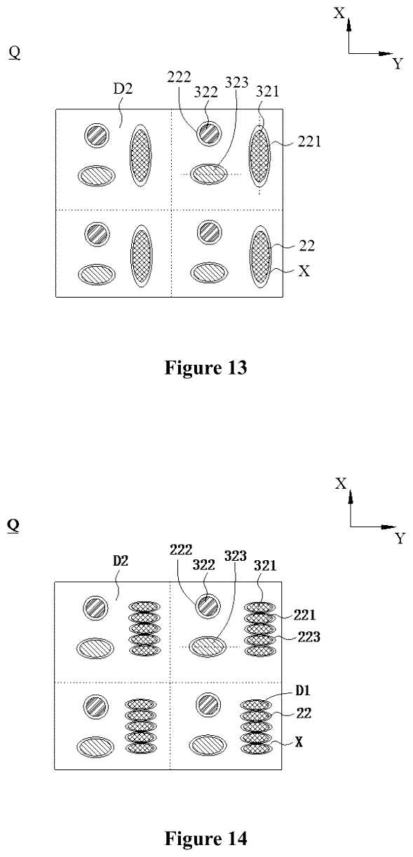

For example, as illustrated in FIG. 13, the pixel opening 22 corresponding to the first light emitting structure 321, the pixel opening 22 corresponding to the second light emitting structure 322, and the pixel opening 22 corresponding to the third light emitting structure 323 each include only one aperture. In addition, the orthographic projection, of the pixel opening 22 corresponding to the first light emitting structure 321, on the substrate 10 is an ellipse. The orthographic projection, of the pixel opening 22 corresponding to the second light emitting structure 322, on the substrate 10 is a circle. The orthographic projection, of the pixel opening 22 corresponding to the third light emitting structure 323, on the substrate 10 is an ellipse. Furthermore, the major axis of the ellipse for the pixel opening 22 corresponding to the first light emitting structure 321 intersects with the major axis of the ellipse for the pixel opening 22 corresponding to the third light emitting structure 323. In this case, the aperture ratio corresponding to the pixel opening 22 is decreased by 22% approximately.

On this basis, as illustrated in FIG. 14, the pixel opening 22 corresponding to the first light emitting structure 321 includes multiple immediately adjacent apertures 223. In this way, the aperture ratio corresponding to the pixel opening 22 can be increased, and is decreased by 15% approximately. In addition, due to the curved edge of the pixel opening 22, almost no color separation or the rainbow pattern displayed on the display panel, to provide better user experience.

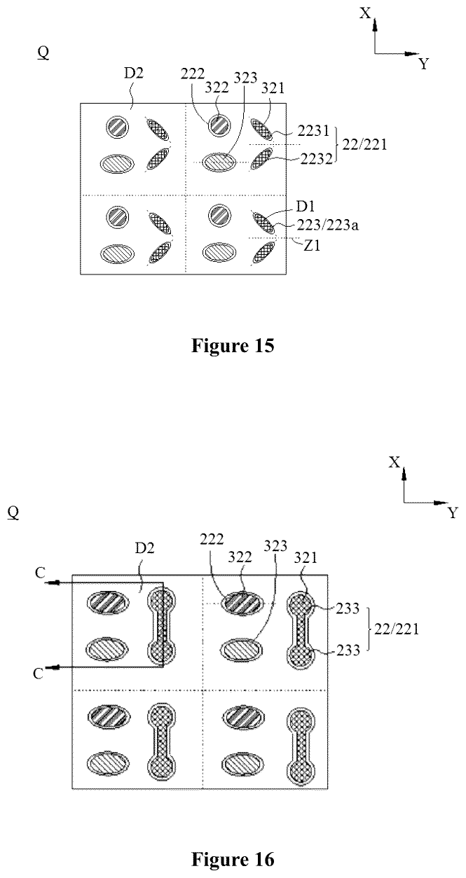

In some embodiments, as illustrated in FIG. 15, the pixel opening 22 corresponding to the first light emitting structure 321 include multiple apertures 223. Each of the apertures 223 has an ellipse orthographic projection. Major axes of the ellipses corresponding to the apertures 223 intersect. In this way, almost no visual aberration occurs while the aperture ratio corresponding to the pixel opening 22 is increased, to improve the display effect of the display panel.

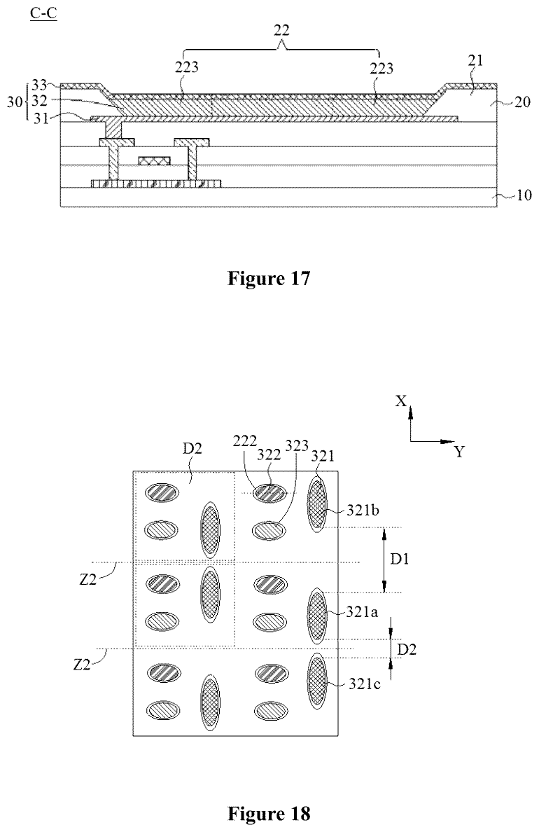

In some embodiments, referring to FIG. 16 and FIG. 17, adjacent apertures 223 are connected.

In the embodiments of the present disclosure, the adjacent apertures 223 are connected without separating the light emitting material in these apertures 223. Therefore, the light emitting structure 32 is large, to improve the brightness of the light emitted by the emitting structure 32 and prolonging a service life of the light emitting structure 32.

Further, the pixel opening 22 is provided with a channel for connecting the adjacent apertures 223. Details about the channel are not limited in the embodiments of the present disclosure. For example, an orthographic projection, of the communicating channel, on the substrate 10 is a rectangle.

It should be noted that light emitting structures 32 arranged in apertures 223 are connected to first electrodes 31, to receive signals transmitted by these first electrodes 31, respectively. In one embodiment, as illustrated in FIG. 14, light emitting structures 32 arranged in respective apertures 223 are connected to the same first electrode 31, to receive a signal transmitted by the first electrode 31. This is not limited in the embodiments of the present disclosure. That is, the light emitting structures 32 arranged in apertures 223 corresponding to the first light emitting structure 321 are connected to respective first electrodes 31 driven by the same pixel circuit, or the same first electrode 31.

In some embodiments, as illustrated in FIG. 15, the multiple apertures 223 are divided into a first-type aperture 2231 and a second-type aperture 2232 that are adjacent. An orthographic projection of the first-type aperture 2231 on the substrate 10 and an orthographic projection of the second-type aperture 2232 on the substrate 10 are symmetrical relative to a first virtual straight line Z1.

The first-type aperture 2231 is adjacent to the second-type aperture 2232. The first-type aperture 2231 and the second-type aperture 2232 are arranged apart. In one embodiment, the first-type aperture 2231 is connected to the second-type aperture 2232. The first-type aperture 2231 and the second-type aperture 2232 are identical or similar in contour. For example, the orthographic projection of the first-type aperture 2231 on the substrate 10 and the orthographic projection of the second-type aperture 2232 on the substrate 10 each are a circle, and the first-type aperture 2231 and the second-type aperture 2232 are identical in contour. In another example, the orthographic projection of the first-type aperture 2231 on the substrate 10 and the orthographic projection of the second-type aperture 2232 on the substrate 10 each are an ellipse, and major axes and minor axes of the two ellipses all intersect with the first virtual straight line Z1. In this case, the first-type aperture 2231 and the second-type aperture 2232 are similar in contour.

In the embodiments of the present disclosure, the orthographic projection of the first-type aperture 2231 on the substrate 10 and the orthographic projection of the second-type aperture 2232 on the substrate 10 are symmetrical relative to the first virtual straight line Z1, and light emitted by the light emitting material in the first-type aperture 2231 and light emitted by the light emitting material in the second-type aperture 2232 are symmetrical relative to the first virtual straight line Z1, to improve reliability. In one embodiment, sizes and shapes of the first-type aperture 2231 and the second-type aperture 2232, and a relative position relationship between the first-type aperture 2231 and the second-type aperture 2232 may be adjusted to control light emitted by the light emitting structure 32. In this way, the amount of the emitted light is approximately constant from various viewpoints, to improve the display effect of the display panel.

In some embodiments, the multiple light emitting structures 32 are divided into a first light emitting structure 321, a second light emitting structure 322, and a third light emitting structure 323 emitting light in different colors. The display panel is divided into pixel units D2. The first light emitting structure 321, the second light emitting structure 322, and the third light emitting structure 323 are arranged in the pixel unit D2.

In the pixel unit D2, the second light emitting structure 322 alternates with the third light emitting structure 323 along a first direction X. The first light emitting structure 321 is arranged on a side of the second light emitting structure 322 and the third light emitting structure 323 along a second direction Y. The first direction X intersects with the second direction Y. In addition, an orthographic projection of the first light emitting structure 321 overlaps an orthographic projection of the second light emitting structure 322 and an orthographic projection of the third light emitting structure 323 along the second direction Y.

The multiple light emitting structures 32 are divided into at least a first light emitting structure 321, a second light emitting structure 322, and a third light emitting structure 323 emitting light in different colors. For example, the first light emitting structure 321 emits light in blue, the second light emitting structure 322 emits light in red, and the third light emitting structure 323 emits light in green.

The light emitting structure emitting light in blue, the light emitting structure emitting light in red and the light emitting structure emitting light in green form the pixel unit D2. The display panel adopts true color, which has better display effect than rendering. In addition, the first light emitting structure 321 is large, which improves a service life of the first light emitting structure 321. The light emitting material with a relatively short service life may be arranged in the light emitting layer of the first light emitting structure to provide better user experience.

The display panel is divided into multiple pixel units D2. The multiple pixel units D2 are arrayed along the first direction X and the second direction Y to adapt to the arrangement of the pixels 30. In one embodiment, the first direction X is perpendicular to the second direction Y.

The pixel units D2 each include a first light emitting structure 321, a second light emitting structure 322, and a third light emitting structure 323. The first light emitting structure 321, the second light emitting structure 322, and the third light emitting structure 323 each may be arranged at the same or different position in the pixel units D2. This is not limited in the embodiments of the present disclosure. In each of the pixel units D2, the second light emitting structure 322 alternates with the third light emitting structure 323 along the first direction X, and the first light emitting structure 321 is arranged on a side of the second light emitting structure 322 and the third light emitting structure 323 along the second direction Y.

In addition, an orthographic projection of the first light emitting structure 321 overlaps an orthographic projection of the second light emitting structure 322 and an orthographic projection of the third light emitting structure 323 along the second direction Y. Therefore, the light emitted by the first light emitting structure 321 and the light emitted by the second light emitting structure 322 can be mixed well, and the light emitted by the first light emitting structure 321 and the light emitted by the third light emitting structure 323 can be mixed well. In this way, the display panel can display images colorfully. In addition, less dispersion results compared with the case in which multiple light emitting structures 32 in the pixel unit D2 are arranged in a row, and therefore display effect of the display panel can be effectively improved.

In some embodiments, as illustrated in FIG. 9 to FIG. 12, the first light emitting structure 321 is divided into multiple first light emitting units D1 arranged along the first direction X.

The first light emitting structure 321 is normally formed depending on the pixel opening 22. On this basis, the pixel opening 22 corresponding to the first light emitting structure 321 includes multiple apertures 223, and the first light emitting structure 321 can be divided into multiple first light emitting units D1. For example, the multiple apertures 223 are arranged in a row along the first direction X, and the first light emitting structure 321 can be divided into multiple first light emitting units D1 arranged along the first direction X. An orthographic projection of the first light emitting unit D1 on the substrate 10 coincides or does not coincide with an orthographic projection of the aperture 223 corresponding to the first light emitting unit D1 on the substrate 10, which is not limited in the embodiments of the present disclosure.

The position relationship between multiple first light emitting units D1 in a same first light emitting structure 321 is not limited in the embodiments of the present disclosure. For example, the first light emitting units D1 are arranged apart. In one embodiment, one first light emitting unit D1 abuts onto another first light emitting unit D1. In another example, the multiple first light emitting units D1 are connected. In one embodiment, the multiple first light emitting units D1 are arranged separately.

In the embodiments of the present disclosure, the first light emitting structure 321 is divided into multiple first light emitting units D1 along the first direction X. Therefore, in the second direction Y, some first light emitting units D1 and the second light emitting structure 322 are staggered, and other first light emitting units D1 and the third light emitting structure 323 are staggered. That is, in the second direction Y, the orthographic projection of some first light emitting units D1 overlap the orthographic projection of the second light emitting structure 322, and the orthographic projection of other first light emitting units D1 overlap the orthographic projection of the third light emitting structure 323, for mixing light, to improve the display effect. In addition, the aperture ratio at the pixel opening 22 corresponding to the first light emitting structure 321 can be increased, which is conducive to an increase in a size of the first light emitting structure. Therefore, the brightness of the light emitted by the first light emitting structure 321 can be improved and the service life of the first light emitting structure 321 can be prolonged, with high reliability.

It should be noted that shapes of respective apertures 223 corresponding to different first light emitting units D1 are not limited in the embodiments of the present disclosure. In some embodiments, at least some of the pixel openings 22 each include adjacent first apertures 223a. The first light emitting unit D1 is arranged in the first aperture 223a. An orthographic projection of the first aperture 223a on the substrate 10 is an ellipse.

In the embodiments of the present disclosure, the orthographic projection of the first aperture 223a on the substrate 10 is an ellipse. Therefore, the roundness of the edge of the first light emitting unit D1 arranged in the first aperture 223a is further improved. In this way, almost no dispersion results, to improve the display effect.

In the first direction X, some first light emitting units D1 and the second light emitting structure 322 are staggered, and other first light emitting units D1 and the third light emitting structure 323 are staggered. That is, the first light emitting structure 321 is longer than the second light emitting structure 322 and the third light emitting structure 323 in the first direction X. On this basis, the first light emitting structure 321 is divided into first light emitting units D1 arranged along the first direction X, and the orthographic projection of the first aperture 223a on the substrate 10 is approximately a circle or ellipse. Therefore, the roundness of the first light emitting units D1 is improved, and therefore less dispersions results.

The first apertures 223a corresponding to different first light emitting units D1 are identical or different in shape, which is not limited in the embodiments of the present disclosure.

In some embodiments, as illustrated in FIG. 12, major axes of ellipses corresponding to at least some of the first apertures 223a are parallel to the first direction X.

As mentioned above, the pixel units D2 are arranged along the first direction X. The second light emitting structure 322 alternates with the third light emitting structures 323 along the first direction X in the pixel unit D2. On this basis, major axes of ellipses corresponding to at least some of the first apertures 223a are parallel to the first direction X. That is, the arrangement of the first apertures 223a is adapted to the arrangement of the pixels in the display panel, to improve the display effect.

In other embodiments, as illustrated in FIG. 9, major axes of ellipses corresponding to at least some of the first apertures 223a are parallel to the second direction Y.

In other embodiments, as illustrated in FIG. 15, major axes of ellipses corresponding to at least some of the first apertures 223a intersect with the first direction X and the second direction Y, and major axes of ellipses corresponding to at least some of adjacent first apertures 223a are symmetrical relative to the second direction Y.

With such layout, apertures 223 with large size can be arranged in a limited space. Therefore, the aperture ratio corresponding to the pixel opening 22 is increased. That is, the aperture rate is decreased less. In one embodiment, the major axes of the ellipses corresponding to the first apertures 223a intersect with both the first direction X and the second direction Y. That is, at least some of the first apertures 223a are inclined relative to the pixels in the display panel. Therefore, the probability of chromatic aberration is reduced, to display images reliably.

In some embodiments, as illustrated in FIG. 11, the first shape X corresponding to the pixel opening 22 where the second light emitting structure 322 is arranged is an ellipse, and a major axis of the ellipse is parallel to the second direction Y.

As described above, the multiple pixel units D2 are arranged along the second direction Y. In the pixel unit D2, the first light emitting structure 321 is arranged on a side of the second light emitting structure 322 and the third light emitting structure 323 along the second direction Y.

Further, the major axis of the ellipse of the pixel opening 22 corresponding to the second light emitting structure 322 is parallel to the second direction Y, and the second light emitting structure 322 is closer to the first light emitting structure 321 in the second direction Y. In addition, a pixel opening 22 corresponding to a second light emitting structure 322 closer to the first light emitting structure 321 has a smaller size in the first direction X, reducing a risk of a failure to prepare the light emitting structures 32 due to extremely small distance between the different pixel openings 22. According to the embodiments of the present disclosure, the light emitting structures 32 in the display panel are distributed densely while the display panel can be fabricated reliably.

Similarly, in some embodiments, the first shape X corresponding to the pixel opening 22 where the third light emitting structure 323 is arranged is an ellipse, and a major axis of the ellipse is parallel to the second direction Y.

In some embodiments, referring to FIG. 18, the display panel includes multiple first light emitting structures 321. The multiple first light emitting structures 321 are classified into a first-type light emitting structure 321a, a second-type light emitting structure 321b and a third-type light emitting structure 321c. Along the first direction X, the second-type light emitting structure 321b and the third-type light emitting structure 321c are arranged on two sides of the first-type light emitting structure 321a respectively. In addition, the second-type light emitting structure 321b and the third-type light emitting structure 321c are adjacent to the first-type light emitting structure 321a.

Along the first direction X, a minimum distance between the first-type light emitting structure 321a and the second-type light emitting structure 321b is D1, and a minimum distance between the first-type light emitting structure 321a and the third-type light emitting structure 321c is D2, where D1 is greater than D2.

In the display panel, the second light emitting structure 322 alternates with the third light emitting structure 323 along the first direction X. In addition, on at least one side of the second light emitting structure 322 and the third light emitting structure 323 in the second direction Y, multiple first light emitting structures 321 are arranged in a row along the first direction X.

Further, the multiple first light emitting structures 321 are divided into the second-type light emitting structure 321b, the first-type light emitting structure 321a, and the third-type light emitting structure 321c that are sequentially arranged in the first direction X. On this basis, if the first light emitting structures 321 each are arranged at the same position throughout the pixel units D2, a minimum distance between the first-type light emitting structure 321a and the second-type light emitting structure 321b is equal to the minimum distance between the third-type light emitting structure 321c and the first-type light emitting structure 321a.

In the embodiments of the present disclosure, the first light emitting structures 321 are arranged at different positions in at least some of the pixel units D2. Therefore, the minimum distance D1 between the first-type light emitting structure 321a and the second-type light emitting structure 321b is greater than the minimum distance D2 between the first-type light emitting structure 321a and the third-type light emitting structure 321c. In this way, the first light emitting structures 321 are arranged differently in the pixel units D2, and therefore less dispersion results and the display effect is improved in comparison with the case that the light emitting structures 32 each are arranged at the same position throughout the pixel units D2.

In some embodiments, as illustrated in FIG. 18, a second virtual straight line Z2 is defined between two pixel units D2 that are adjacent in the first direction X. The second virtual straight line Z2 is parallel to the second direction Y. A distance between the second virtual straight line Z2 and a center of one of the two adjacent pixel units D2 is equal to a distance between the second virtual straight line Z2 and a center of the other of the two adjacent pixel units D2. Two first light emitting structures 321 in the two adjacent pixel units D2 are symmetrical relative to the second virtual straight line Z2.

One of the two adjacent pixel units D2 in the first direction X is provided with the first-type light emitting structure 321a, and the other of the two adjacent pixel units D2 is provided with the second-type light emitting structure 321b. The second virtual straight line Z2 is defined between the two adjacent pixel units D2. The distance between the second virtual straight line Z2 and the center of one of the two adjacent pixel units D2 is equal to the distance between the second virtual straight line Z2 and the center of the other of the two adjacent pixel units D2. In FIG. 15, the pixel unit D2 is indicated by a dashed box. The center of the pixel unit D2 mentioned in the embodiments of the present disclosure refers to a geometric center of the pixel unit D2. The distance between the second virtual straight line Z2 and the center of one of the two adjacent pixel units D2 is equal to the distance between the second virtual straight line Z2 and the center of the other of the two adjacent pixel units D2, in the first direction X.

As described above, the minimum distance D1 between the first-type light emitting structure 321a and the second-type light emitting structure 321b is greater than the minimum distance D2 between the first-type light emitting structure 321a and the third-type light emitting structure 321c. On this basis, in the embodiments of the present disclosure, first light emitting structures 321 in adjacent pixel units D2 are arranged symmetrically relative to the second virtual straight line Z2. It should be noted that due to factors such as an error in the process, the first light emitting structures 321 in the adjacent pixel units D2 are unnecessarily identical precisely. The first light emitting structures 321 are regarded as symmetrical relative to the second virtual straight line Z2 within the acceptable margin of error. The center of the first light emitting structure 321 in one pixel unit D2 is distanced from the center of the pixel unit D2 in the first direction X, and other pixel units D2 adjacent to the pixel unit D2 are arranged symmetrically relative to the pixel unit D2. In this way, the first light emitting structures 321 in at least some of pixel units D2 are arranged at irregular intervals. Therefore, almost no dispersion results, to improve the display effect.

In the embodiments of the present disclosure, two adjacent pixel units D2 in the first direction X form a duplication unit. In the display panel, the light emitting structures 32 are arranged identically throughout duplication units. In addition, the reduplication units are arranged along the first direction X and the second direction Y, to adapt to the arrangement of the pixels in the display panel. In this way, the light emitting structures 32 in the display panel are arranged regularly, and therefore can be fabricated easily.

In some embodiments, as illustrated in FIG. 11, the first shapes X of the pixel openings 22 corresponding to the first light emitting structure 321, the second light emitting structure 322, and the third light emitting structure 323 each are a circle.

The circle is completely round, and edges of the first light emitting structure 321, the second light emitting structure 322 and the third light emitting structure 323 formed in the pixel openings 22 each are completely round. Therefore, almost no dispersion results, to improve the display effect. In addition, since the first shape X that is a circle is completely round, the first light emitting structure 321, the second light emitting structure 322 and the third light emitting structure 323 each have the same structure throughout, and therefore can emit light reliably.

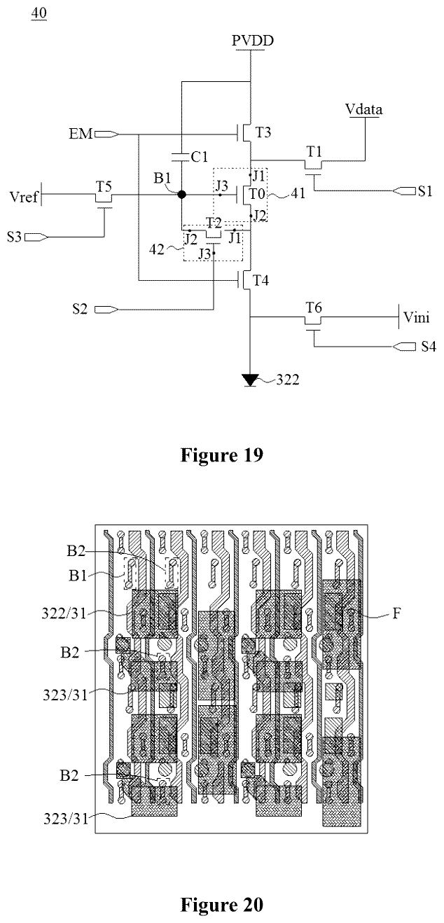

In some embodiments, referring to FIG. 19, the display panel further includes a first pixel circuit 40 for controlling the second light emitting structure 322. The first pixel circuit 40 includes a first driving transistor 41, a first threshold compensation transistor 42, and a first connecting part B1. A first terminal J1 of the first threshold compensation transistor 42 is connected to a second terminal J2 of the first driving transistor 41. The second terminal J2 of the first threshold compensation transistor 42 is electrically connected to a gate J3 of the first driving transistor 41 through the first connecting part B1.

The first pixel circuit 40 is configured to drive the second light emitting structure 322 to emit light. Details about the first pixel circuit 40 is not limited in the embodiments of the present disclosure. For example, the first pixel circuit 40 has the 7T1C structure. That is, the first pixel circuit 40 includes seven transistors and one capacitor.

The first pixel circuit 40 includes the first driving transistor 41 and the first threshold compensation transistor 42. The first threshold compensation transistor 42 and the first driving transistor 41 each include a first terminal J1, a second terminal J2 and a gate J3. The first threshold compensation transistor 42 is connected between the gate J3 and the second terminal J2 of the first driving transistor 41, to provide a data voltage signal for the gate J3 of the first driving transistor 41 and provide compensation for a voltage signal. Therefore, the first driving transistor 41 can be switched on reliably.

The second terminal J2 of the first threshold compensation transistor 42 is electrically connected to a gate J3 of the first driving transistor 41 through the first connecting part B1. The first connecting part B1 is configured to transmit signals inside the first pixel circuit 40. The first connecting part B1 is generally arranged in a layer different from a conductor connected to the first connecting part B1, and is electrically connected to the conductor via a through hole.

In some embodiments, referring to FIG. 19 and FIG. 20, the orthographic projection of the first electrode 31 corresponding to the second light emitting structure 322 on the substrate and an orthographic projection of the first connecting part B1 on the substrate are spaced. FIG. 17 partially shows the film layers of the display panel.

The case that the orthographic projection of the first electrode 31 on the substrate overlaps the orthographic projection of the first connecting part B1 on the substrate likely results in an additional capacitor structure under a voltage signal, and consequently a capacitance difference between positions of the display panel. As a result, the second light emitting structures 322 fail to evenly illuminate the screen.

In view of this, in the embodiments of the present disclosure, the orthographic projection of the first electrode 31 corresponding to the second light emitting structure 322 on the substrate and the orthographic projection of the first connecting part B1 on the substrate are space. That is, the orthographic projection of the first electrode 31 for driving the second light emitting structure 322 to emit light on the substrate does not overlap the orthographic projection of the first connecting part B1 on the substrate. In this way, no capacitance difference results and therefore the screen can be evenly illuminated.

Similarly, an orthographic projection of the first electrode 31 corresponding to the third light emitting structure 323 on the substrate and an orthographic projection of the first connecting part B1 on the substrate are spaced.

In addition, in FIG. 20, at least some of the first electrodes 31 are covered with a block structure F. As can be seen from FIG. 16, the block structure F transmits a PVDD signal to the first electrode 31. The first electrode 31 controls, under the driving of the PVDD signal, the light emitting structure to emit light.

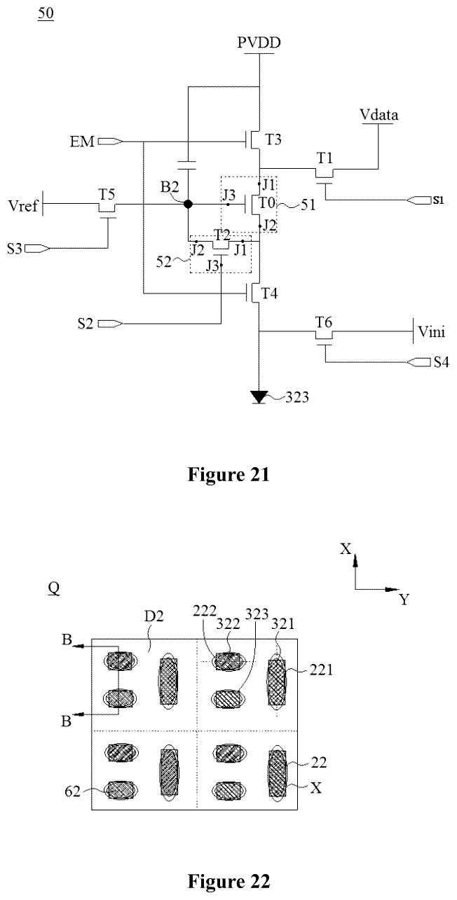

In some embodiments, referring to FIG. 20 and FIG. 21, the display panel further includes a second pixel circuit 50 for controlling the third light emitting structure 323. The second pixel circuit 50 includes a second driving transistor 51, a second threshold compensation transistor 52 and a second connecting part B2. A first terminal J1 of the second threshold compensation transistor 52 is connected to a second terminal J2 of the second driving transistor 51. The second terminal J2 of the second threshold compensation transistor 52 is electrically connected to a gate J3 of the second driving transistor 51 through the first connecting part B1.

Orthographic projections of first electrodes 31 corresponding to at least some of the third light emitting structures 323 on the substrate 10 each overlap the orthographic projection of the second connecting part B2 on the substrate 10, with the overlaps being equal in size.

The second pixel circuit 50 is configured to drive the third light emitting structure 323 to emit light. Details about the second pixel circuit 50 are not limited in the embodiments of the present disclosure. For example, the second pixel circuit 50 has the same structure as the first pixel circuit 40, and thus is not detailed herein. Reference can be made to the first pixel circuit 40 for further details.

The second pixel circuit 50 includes the second connecting part B2. The orthographic projection of the second connecting part B2 on the substrate 10 overlaps the orthographic projection of the first electrode 31 corresponding to the third light emitting structure 323 on the substrate. The case that the overlaps between the first electrodes 31 corresponding to third light emitting structures 323 and the second connecting part B2 are different sizes is likely to results in a capacitance difference between positions of the display panel under a voltage signal. Consequently, the second light emitting structures 322 fail to evenly illuminate the screen.

In view of this, in the embodiments of the present disclosure, the overlaps between the first electrodes 31 corresponding to the third light emitting structures 323 and the second connecting part B2 are equal in size. Therefore, the capacitances between the first electrodes 31 corresponding to the third light emitting structures 323 and the second connecting part B2 are equal or approximately equal, and then the second light emitting structures 322 can evenly illuminate the screen.

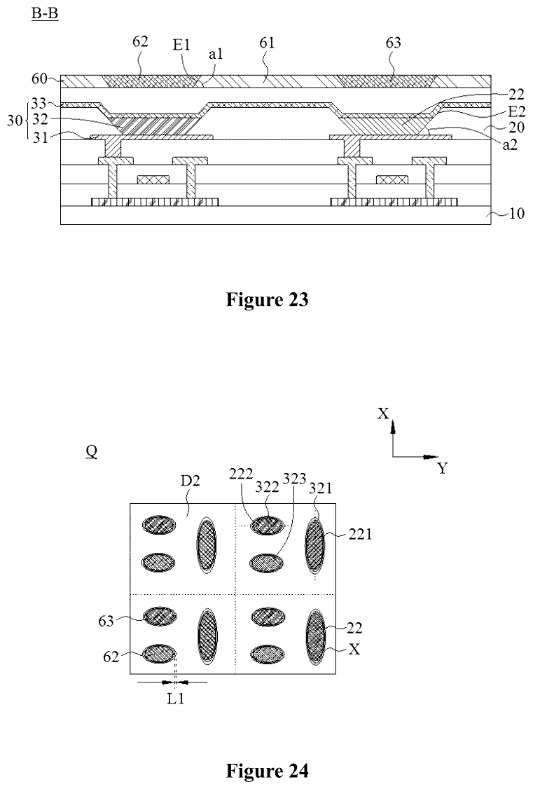

In some embodiments, referring to FIG. 22 and FIG. 23, the display panel further includes a light filtering layer 60 arranged on a side, of the pixels 30, away from the substrate 10. The light filtering layer 60 includes a light shielding part 61 and a light filtering part 62. Multiple first apertures 63 are defined by the light shielding part 61. The light filtering part 62 is at least partially arranged in the first aperture 63. An orthographic projection of the light shielding part 61 on the substrate 10 at least partially overlaps the orthographic projection of the first electrode 31 on the substrate 10.

The light filtering layer 60 is arranged on the side of the pixels 30 away from the substrate 10. The light filtering layer 60 includes the light filtering part 62 and the light shielding part 61. The light shielding part 61 is made of opaque material. Light incident in the display panel is reflected the light emitting structures 32 or the pixel circuits. The reflected light is blocked or absorbed by the light shielding part 61, and fail to be reflected once more. The light shielding part 61 prevents reflection to a certain extent, to improve the display effect.

Multiple first apertures 63 are defined by the light shielding part 61, and the multiple first apertures 63 correspond to the pixel openings 22. For example, an orthographic projection of the first aperture 63 on the substrate 10 at least partially overlaps an orthographic projection of the pixel opening 22 on the substrate 10. The light filtering part 62 is embedded in the first aperture 63. The light filtering part 62 is completely arranged in the first aperture 63. In one embodiment, the light filtering part 62 is partially arranged on a side, of the light shielding part 61, away from the substrate 10 and covers the light shielding part 61, which is not limited in the embodiments of the present disclosure.

The light filtering part 62 usually corresponds to the light emitting structures 32. The light emitted by the light emitting structure 32 is filtered by the light filtering part 62, and the light in desired color can be emitted. Therefore, the display panel can display images precisely. In some embodiments, the light filtering parts 62 are of multiple types, including a red light filtering part 62 corresponding to the light emitting structure 32 emitting light in red, a green light filtering part 62 corresponding to the light emitting structure 32 emitting light in green, and a blue-light filtering part 62 corresponding to the light emitting structure 32 emitting light in blue.

On this basis, if the orthographic projection of the first aperture 63 on the substrate 10 is larger than the orthographic projection of the first electrode 31 on the substrate 10, there are a region where the first electrode 31 is arranged and a region where no first electrode 31 is arranged at a position, of the display panel, corresponding to the first aperture 63, resulting in varying reflectivity due to factors such as material of the first electrode 31. Consequently, the display panel fails to display images well.

In view of this, the orthographic projection of the light shielding part 61 on the substrate 10 at least partially overlaps the orthographic projection of the first electrode 31 on the substrate 10 in the embodiments of the present disclosure, and the orthographic projection of the first openings 63 defined by the light shielding part 61 on the substrate 10 completely or roughly overlaps the orthographic projection of the first electrode 31 on the substrate 10 to reduce a proportion of whose projection does not overlap with the projection of the first electrode 31 in the first aperture 63. Therefore, a risk of abnormal display due to the varying reflectivity of the first opening 63 can be reduced, to improve the display effect and the display reliability.

In addition, the light emitted by the light emitting structure 32 passes through the first opening 63 before emitted out of the display panel. Therefore, a shape of light emitted by the light emitting structure 32 depends on the pixel opening 22 and the first aperture 63 that correspond to the light emitting structure 32. On this basis, the shape of emitted light is variable by adjusting shapes of the pixel opening 22 and the first aperture 63 and a relative position relationship between the pixel opening 22 and the first aperture 63, to prevent the dispersion.

Further, in some embodiments, the orthographic projection of the first aperture 63 on the substrate 10 is arranged within the orthographic projection of the pixel opening 22 on the substrate 10. Therefore, the first aperture 63 can better match the first electrode 31 The orthographic projection of the first opening 63 on the substrate 10 can maximally overlap the orthographic projection of the first electrode 31 on the substrate 10 without enlarging the first opening 63. The risk of abnormal display of the display panel due to the varying reflectivity of the first aperture 63 can be reduced, to improve the display effect and display reliability.

It should be noted that in the embodiments of the present disclosure, a shape of the orthographic projection, of the first aperture 63 on the substrate 10 is identical to or different from a shape of the orthographic projection of the pixel opening 22 on the substrate 10. This is not limited in the embodiments of the present disclosure as long as the light finally emitted from the first aperture 63 is not reflected and less dispersion results.

The shape of the orthographic projection of the first aperture 63 on the substrate 10 mentioned in the embodiments of the present disclosure refers to a counter of the orthographic projection of the first opening 63 on the substrate 10. The orthographic projection of the first aperture 63 on the substrate 10 may further have an inner edge (not illustrated in the drawings). A size and a shape of the inner edge of the orthographic projection of the first aperture 63 on the substrate 10 are not limited in the embodiments of the present disclosure.

In some embodiments, referring to FIG. 24, the orthographic projection of the first aperture 63 on the substrate includes a curved edge.

A shape of the orthographic projection, of the first aperture 63 on the substrate is not limited in the embodiments of the present disclosure. For example, the orthographic projection of the first aperture 63 on the substrate is a circle or an ellipse.

In the embodiments of the present disclosure, the shape of the first aperture 63 is such adjusted that the orthographic projection of the first aperture 63 on the substrate includes a curved edge. Therefore, the light emitted by the light emitting structure 32 is less reflected when passing through the first aperture 63, and then less dispersion results, to improve the display effect.

In some embodiments, a minimum distance between a contour of the orthographic projection of the first opening 63 on the substrate and a contour of the orthographic projection of the pixel opening 22 on the substrate is L1. L1 is less than or equal to 1 μm. In some embodiments, L1 is selected from 1 μm, 0.6 μm, 0.4 μm, 0.1 μm, and 0.05 μm.

As described above, the orthographic projection of the first aperture 63 on the substrate 10 is arranged within the orthographic projection of the pixel opening 22 on the substrate 10. On this basis, the orthographic projection of the first aperture 63 on the substrate 10 includes a curved edge, and the light is less reflected when passing through first opening 63, and therefore less dispersion results.

Further, the first aperture 63 is limited and the minimum distance L1 between the contour of the orthographic projection of the first aperture 63 on the substrate 10 and the contour of the orthographic projection, of the pixel opening 22 on the substrate 10 is not greater than 1 μm. In this way, the first aperture 63 is relatively large and light can be maximally emitted out of the first aperture 63, to improve the brightness and display effect.

In some embodiments, as illustrated in FIG. 23, the light shielding part 61 includes a first edge E1 towards the first aperture 63. The pixel limiting part 21 includes a second edge E2 towards the pixel opening 22. An angle between the first edge E1 and a plane where the substrate 10 is arranged is α1. An angle between the second edge E2 and the plane where the substrate 10 is arranged is α2. α1 is greater than or equal to 30 degrees and less than or equal to 70 degrees, and α2 is greater than or equal to 30 degrees and less than or equal to 60 degrees.

The first edge E1 surrounds the first aperture 63, and the second edge E2 surrounds the pixel opening 22. The first edge E1 and the second edge E2 are generally inclined relative to the plane where the substrate 10 is arranged. The shape of the emitted light depends on the extent of inclination of the first edge E1 relative to the plane where the substrate 10 is arranged and the extent of inclination of the second edge E2 relative to the plane where the substrate 10 is arranged. In view of this, in the embodiments of the present disclosure, the angle between the first edge E1 and the plane where the substrate 10 is arranged is set to α1 which is greater than or equal to 30 degrees and less than or equal to 70 degrees, and the angle between the second edge E2 and the plane where the substrate 10 is arranged is set to α2 which is greater than or equal to 30 degrees and less than or equal to 60 degrees, and a maximum inclination angle of the light emitted out of the display panel can be limited. Therefore, the finally emitted light is less reflected, and thus less dispersion results, to improve the display effect.

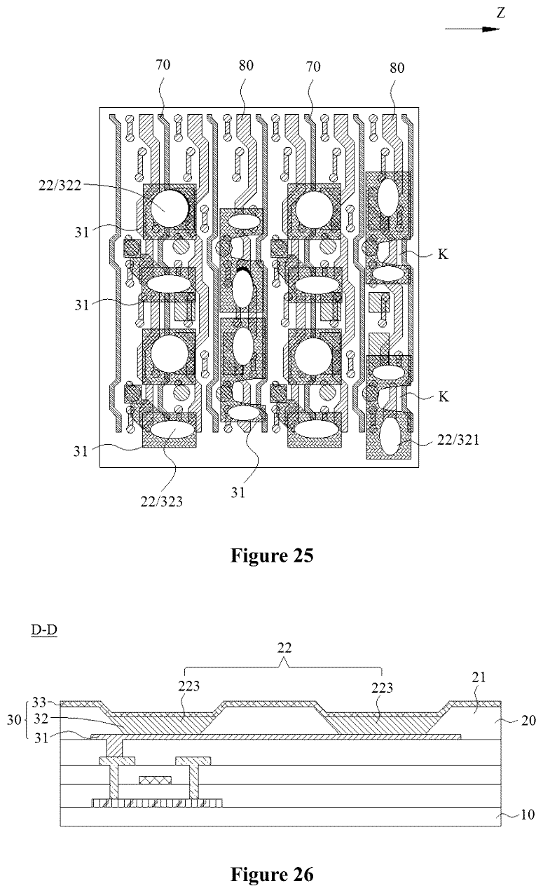

In some embodiments, referring to FIG. 25 and FIG. 26, the display panel further includes data wiring 70 and power supply wiring 80 that are arranged on a side of the substrate 10. The first electrode 31 has a gap K, that is, an edge of the first electrode 31 curves inwards. An orthographic projection of the data wiring 70 on the substrate 10 overlaps an orthographic projection of the gap K on the substrate 10. The power supply wiring 80 overlaps the data wiring 70 along a third direction Z. The third direction Z intersects with a direction in which the data wiring 70 extends.

The data wiring 70 is configured to transmit a data signal. The power supply line 80 is configured to transmit a power supply signal. The power supply wiring 80 overlaps the data wiring 70 along the third direction Z. Different from the arrangement of the pixels in the display panel, the third direction Z is parallel to either the first direction or the second direction, or the third direction Z intersects with both the first direction and the second direction, which is not limited in the embodiments of the present disclosure.

Generally, a single data line 70 is electrically connected to all pixels 30 arranged in a same column. All the light emitting structures 32 in the whole column of pixels 30 may fail to emit light properly when the data line 70 malfunctions. In this case, the malfunctioning data line is replaced with another line.

However, the first electrode 31 corresponding to the first light emitting structure 321 that is generally longer is larger in size. A damage to the data line 70 at the first light emitting structure 321 may result in failure over a long distance in the column of pixels 30 corresponding to the data line 70. Therefore, the data line 70 in the pixel circuit corresponding to the first light emitting structure 321 is significantly different from the data line 70 in the pixel circuit corresponding to the second light emitting structure 322 or the third light emitting structure 323 in length and load, and then the pixel circuits function differently, resulting in uneven display.

In view of this, in the embodiments of the present disclosure, the first electrode 31 is provided with a gap K. The damaged data line 70 can be repaired in the right position due to the gap K. Therefore, another line for repairing the damaged data line 70 is short, and then the pixel circuits are different slightly, contributing to even display.

For example, the multiple light emitting structures 32 are arranged as illustrated in FIG. 2. In this case, the gap K on the first electrode 31 corresponding to the first light emitting structure 321 may be arranged between the second light emitting structure 322 and the third light emitting structure 323. The data lines 70 in different columns can be repaired at relatively similar positions, and then the pixel circuits are different slightly, contributing to even display and the display reliability.

It should be noted that, as illustrated in FIG. 25, the first electrode 31 corresponding to the first light emitting structure 321 is larger than the first electrode 31 corresponding to the second light emitting structure 322 and the first electrode 31 corresponding to the third light emitting structure 323. Further, the rounder the orthographic projection of the pixel opening 22 is, the less the light is diffracted. On the one hand, the case that the pixel opening 22 corresponding to the first light emitting structure 321 includes only one aperture may result in excessive large pixel opening 22, adversely affecting the arrangement of other surrounding light emitting structures. On the other hand, excessively small pixel opening 22 corresponding to the first light emitting structure 321 may adversely affect the aperture ratio, resulting in poor display effect. In addition, the first light emitting structure 321 may be at extremely short distances from other light emitting structures due to inappropriate pixel opening 22 corresponding to the first light emitting structure 321, increasing difficulty in manufacture of a mask and evaporation of the light emitting structures.

In view of this, in the embodiments of the present disclosure, the pixel opening 22 corresponding to the first light emitting structure 321 includes multiple apertures. Further, the orthographic projection of the aperture on the substrate includes a curved edge. Therefore, less dispersion results without decreasing the opening aperture, and the display effect can be improved. In addition, the first light emitting structure 321 does not affect the arrangement of other surrounding light emitting structures, and manufacture of the mask and evaporation of the light emitting structures can be less difficult.

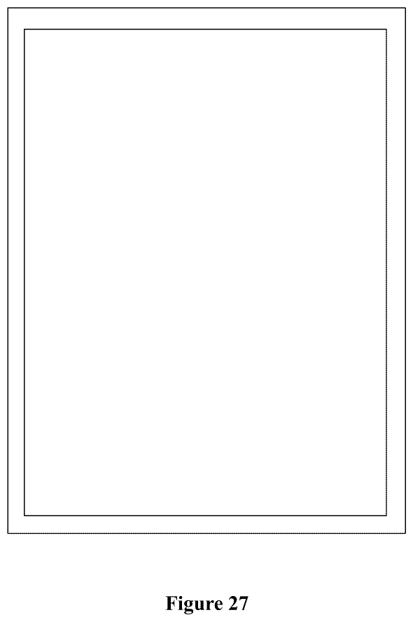

In one embodiment, referring to FIG. 27, a display device is provided according to embodiments of the present disclosure. The display device includes the display panel according to any one of the above embodiments.

It should be noted that the display device according to the embodiments of the present disclosure has the same beneficial effects as the display panel according to any one of the above embodiments, and reference can be made to the above embodiments for details.

The embodiments of the present disclosure as disclosed above are only for the convenience of understanding the present disclosure, instead of intending to limit the present disclosure. The present disclosure relates can make various modifications and variations to the form and details of implementation without departing from the spirit and scope disclosed in the present disclosure. However, the protection scope of the present disclosure shall be subject to the scope defined in the claims.

Only some embodiments of the present disclosure are described above. Replacement of other connection manners described above can refer to the corresponding process in the above method embodiments, and is not repeated here for convenience and simplicity of description. It should be understood that the protection scope of the present disclosure is not limited thereto. Any technician familiar with the field can easily think of various equivalent modifications or replacements within the scope disclosed in the present disclosure, and these modifications or replacements should be included in the protection scope of the present disclosure.

1. A display panel, comprising:
a substrate;
a pixel definition layer, arranged on a side of the substrate and comprising a pixel limiting part and pixel openings defined by the pixel limiting part; and
pixels, each comprising a first electrode and a light emitting structure at least partially arranged in the corresponding pixel opening, wherein the pixel opening at least partially exposes the first electrode, an orthographic projection of the pixel opening on the substrate is a first shape, and the first shape at least partially comprises a curved edge.

2. The display panel according to claim 1, wherein
the first shape is a circle or an ellipse.

3. The display panel according to claim 2, wherein
the light emitting structures are classified into a first light emitting structure and a second light emitting structure configured to emit light in different colors; and
the pixel openings are classified into a first pixel opening accommodating the first light emitting structure and a second pixel opening accommodating the second light emitting structure, and the first shape corresponding to the first pixel opening and the first shape corresponding to the second pixel opening each are an ellipse, and wherein a major axis of the ellipse corresponding to the first pixel opening intersects a major axis of the ellipse corresponding to the second pixel opening.

4. The display panel according to claim 2, wherein
at least some of the pixel openings each comprise adjacent apertures, and orthographic projections of at least some of the apertures on the substrate each are at least a circle or an ellipse.

5. The display panel according to claim 4, wherein
the adjacent apertures are connected.

6. The display panel according to claim 4, wherein
the adjacent apertures are classified into a first-type aperture and a second-type aperture, and an orthographic projection of the first-type aperture on the substrate and an orthographic projection of the second-type aperture on the substrate are symmetrical relative to a first virtual straight line.

7. The display panel according to claim 4, wherein
the light emitting structures are classified into a first light emitting structure, a second light emitting structure and a third light emitting structure configured to emit light in different colors;
the display panel further comprises pixel units, and the pixel unit comprises the first light emitting structure, the second light emitting structure and the third light emitting structure; and
in the pixel unit, the second light emitting structure alternates with the third light emitting structure along a first direction, the first light emitting structure is arranged on a side of the second light emitting structure and the third light emitting structure along a second direction, and an orthographic projection of the first light emitting structure overlaps an orthographic projection of the second light emitting structure and an orthographic projection of the third light emitting structure along the second direction, wherein the first direction intersects with the second direction.

8. The display panel according to claim 7, wherein
the first light emitting structure comprises first light emitting units arranged along the first direction,
wherein the first light emitting units are arranged in the first apertures, respective orthographic projections of the first apertures on the substrate ellipses, wherein
major axes of the ellipses corresponding to at least some of the first apertures are parallel to the first direction; and/or
major axes of the ellipses corresponding to at least some of the first apertures are parallel to the second direction; and/or
major axes of the ellipses corresponding to at least some of the first apertures intersect with the first direction and the second direction, and major axes of ellipses corresponding to at least some of the adjacent first apertures are symmetrical relative to the second direction.

9. The display panel according to claim 7, wherein
the first shape corresponding to the pixel opening where the second light emitting structure is arranged is an ellipse, and a major axis of the ellipse is parallel to the second direction.

10. The display panel according to claim 7, wherein
first light emitting structures are classified into a first-type light emitting structure, a second-type light emitting structure and a third-type light emitting structure;
along the first direction, the second-type light emitting structure and the third-type light emitting structure are arranged on two sides of the first-type light emitting structure respectively, and the second-type light emitting structure and the third-type light emitting structure are adjacent to the first-type light emitting structure; and
along the first direction, the first-type light emitting structure is arranged at a distance D1 from the second-type light emitting structure is D1 and is arranged at a distance D2 from the third-type light emitting structure, wherein D1 is greater than D2,
wherein a second virtual straight line is defined between two adjacent pixel units along the first direction, the second virtual straight line is parallel to the second direction, and the second virtual straight line are at equal distances from carters of the two pixel units; and
the first light emitting structures in the two adjacent pixel units are symmetrical relative to the second virtual straight line.

11. The display panel according to claim 7, wherein
the first shapes of the pixel openings corresponding to the first light emitting structure, the second light emitting structure and the third light emitting structure each are a circle.

12. The display panel according to claim 7, further comprising:
a first pixel circuit configured to control the second light emitting structure, wherein the first pixel circuit comprises a first driving transistor, a first threshold compensation transistor and a first connecting part, a first terminal of the first threshold compensation transistor is connected to a second terminal of the first driving transistor, and a second terminal of the first threshold compensation transistor is electrically connected to a gate of the first driving transistor through the first connecting part, and wherein
an orthographic projection of the first electrode corresponding to the second light emitting structure on the substrate and an orthographic projection of the first connecting part on the substrate are spaced; and/or
an orthographic projection of the first electrode corresponding to the third light emitting structure on the substrate and the orthographic projection of the first connecting part on the substrate are spaced.

13. The display panel according to claim 7, further comprising:
a second pixel circuit configured to control the third light emitting structure, wherein the second pixel circuit comprises a second driving transistor, a second threshold compensation transistor and a second connecting part, a first terminal of the second threshold compensation transistor is connected to a second terminal of the second driving transistor, and a second terminal of the second threshold compensation transistor is electrically connected to a gate of the second driving transistor through the first connecting part, and wherein
orthographic projections of the first electrodes corresponding to at least some of the third light emitting structures on the substrate overlap orthographic projections of the corresponding second connecting parts on the substrate, and the overlaps are equal in size.

14. The display panel according to claim 1, further comprising:
a light filtering layer arranged on a side of the pixels away from the substrate, wherein the light filtering layer comprises a light shielding part and a light filtering part, first apertures are defined by the light shielding part, and the light filtering part is at least partially arranged in the corresponding first aperture, and an orthographic projection of the light shielding part on the substrate at least partially overlaps an orthographic projection of the first electrode on the substrate.

15. The display panel according to claim 14, wherein
an orthographic projection of the first aperture on the substrate is within the orthographic projection of the pixel opening on the substrate.

16. The display panel according to claim 15, wherein
the orthographic projection of the first aperture on the substrate comprises a curved edge.

17. The display panel according to claim 15, wherein
a contour of the orthographic projection of the first aperture on the substrate is at a distance of L1 from a contour of the orthographic projection of the pixel opening on the substrate, and L1 is less than or equal to 1 μm.

18. The display panel according to claim 15, wherein
the light shielding part comprises a first edge towards the first aperture, the pixel limiting part comprises a second edge towards the pixel opening, the first edge is at an angle of α1 to a plane where the substrate is arranged, and the second edge is at an angle of α2 to the plane where the substrate is arranged, and wherein 30°≤α1≤70°, and 30°≤α2≤60°.

19. The display panel according to claim 1, further comprising:
data wiring and power supply wiring that are arranged on a side of the first electrode towards the substrate, and wherein the first electrode has a gap formed by an edge curving inwards, and an orthographic projection of the data wiring on the substrate overlaps an orthographic projection of the gap on the substrate, the power supply wiring alternates with the data wring along the third direction, wherein the third direction intersects with a direction in which the data wring extends.

20. A display device, comprising a display panel,
wherein the display panel comprises:
a substrate;
a pixel definition layer, arranged on a side of the substrate and comprising a pixel limiting part and pixel openings defined by the pixel limiting part; and
pixels, each comprising a first electrode and a light emitting structure at least partially arranged in the corresponding pixel opening, wherein the pixel opening at least partially exposes the first electrode, an orthographic projection of the pixel opening on the substrate is a first shape, and the first shape at least partially comprises a curved edge.
